(19) United States
(12) Patent Application Publication
(10) Pub. No.: US 2026/0226619 A1
(43) Pub. Date: Aug. 6, 2026

(54) ATOMIC LAYER DEPOSITION DEVICE

(71) Applicant: Panasonic Intellectual Property Management Co., Ltd., Osaka (JP)

(72) Inventors: NAOMI KURIHARA, Osaka (JP); MIWA OGAWA, Osaka (JP)

(21) Appl. No.: 19/146,599

(22) PCT Filed: Jan. 17, 2024
(86) PCT No.: PCT/JP2024/001147

§ 371 Date: Jul. 9, 2025

(30) Foreign Application Priority Data
Jan. 30, 2023 (JP) 2023-012123

(51) Int. Cl. C23C 16/455; C23C 16/54

(52) U.S. Cl. CPC C23C 16/45544; C23C 16/54

(57) ABSTRACT

Provided is an atomic layer deposition device that can form a compound layer with high productivity even on a substrate having a porous portion on a surface thereof. Device (atomic layer deposition device) (10) that is disclosed includes conveyor (120) and deposition unit (200). Deposition unit (200) includes a plurality of feeders (210) and a plurality of exhausters (220). Each of the plurality of feeders (210) is sandwiched between adjacent two of the exhausters (220). The plurality of feeders (210) includes a plurality of purge gas feeders (213), first raw material feeder (211), and second raw material feeder. Deposition unit (200) includes first purge region (PRI) to third purge region (PR3), first raw material feed region (MR1), and second raw material feed region. At least one purge region selected from the group consisting of first purge region (PR1) to third purge region (PR3) includes two or more of the purge gas feeders.

### TECHNICAL FIELD

The present disclosure relates to an atomic layer deposition device.

### BACKGROUND

An atomic layer deposition device can form a compound layer on a substrate by sequentially spraying different gases onto the substrate. Various proposals have been made on atomic layer deposition devices.

Patent Literature 1 (U.S. Patent Publication No. 2013/0064977) discloses a method for forming an atomic layer on a substrate using a drum including a film formation head. In this method, the substrate is conveyed to move around the drum.

Patent Literature 2 (U.S. Patent Publication No. 2013/0064977) discloses a device in which a head is disposed on each of two sides of a substrate and atomic layers are simultaneously deposited on the two sides of the substrate. In this device, a gas bearing keeps the distances between the heads and the substrate constant.

### CITATION LIST

### Patent Literature

PTL 1: U.S. Patent Publication No. 2013/0064977
PTL 2: U.S. Patent Publication No. 2012/0196050

### SUMMARY

Film formation by an atomic layer deposition method requires gas that is fed to arrive at a surface of a substrate. However, when a substrate having a porous portion on a surface is used, conventional manufacturing methods may have problems. One object of the present disclosure is to provide an atomic layer deposition device that enables formation of a compound layer with high productivity even for a substrate having a porous portion on a surface.

One aspect of the present disclosure relates to an atomic layer deposition device. The atomic layer deposition device is an atomic layer deposition device for forming a compound layer on a substrate by an atomic layer deposition method, the device includes:
a conveyor for conveying the substrate in a conveyance direction, and
at least one deposition unit disposed to face the substrate.

The deposition unit includes a plurality of feeders and a plurality of exhausters, the plurality of feeders and plurality of exhausters being arranged along the conveyance direction to face the substrate,
each of a plurality of feeders is sandwiched between adjacent two of the exhausters,
the plurality of feeders includes a plurality of purge gas feeders for feeding a purge gas, at least one first raw material feeder for feeding a first raw material, and at least one second raw material feeder for feeding a second raw material,
formation of the compound layer includes repetition of a process including feeding of the first raw material to the substrate and feeding of the second raw material to the substrate,
the deposition unit includes
   a first purge region, a second purge region, and a third purge region arranged along the conveyance direction,
   a first raw material feed region disposed between the first purge region and the second purge region, and
   a second raw material feed region disposed between the second purge region and the third purge region,
the first raw material feed region includes the at least one first raw material feeder,
the second raw material feed region includes the at least one second raw material feeder, and
at least one purge region selected from the group consisting of the first purge region, the second purge region, and the third purge region includes two or more of the purge gas feeders.

According to the atomic layer deposition device of the present disclosure, a compound layer can be formed with high productivity even for a substrate having a porous portion on a surface of the substrate.

### BRIEF DESCRIPTION OF THE DRAWINGS

FIG. 1 is a diagram schematically illustrating a configuration of an atomic device deposition device according to a first exemplary embodiment.

FIG. 2 is a diagram schematically illustrating a configuration of an example of a deposition unit.

FIG. 3A is a diagram schematically illustrating a configuration of another example of the deposition unit.

FIG. 3B is a diagram schematically illustrating a configuration of another example of the deposition unit.

FIG. 4 is a diagram schematically illustrating a configuration of another example of the deposition unit.

FIG. 5 is a diagram schematically illustrating a configuration of another example of the deposition unit.

### DESCRIPTION OF EMBODIMENT

Exemplary embodiments according to the present disclosure will be described hereinafter with reference to examples, but the present disclosure is not limited to the examples that will be described below. Specific numerical values and materials may be described as examples in the following description, but other numerical values and materials may be employed as long as an effect of the present disclosure can be obtained. In the present specification, a phrase “numerical value A to numerical value B” includes numerical value A and numerical value B, and can be construed as “more than or equal to numerical value A and less than or equal to numerical value B”. In the following description, in a case where lower limits and upper limits of numerical values related to specific physical properties, conditions, or the like are illustrated, any of the illustrated lower limits and any of the illustrated upper limits can be arbitrarily combined unless the lower limit is more than or equal to the upper limit. When example constituent elements or example methods are presented in the following description, only one of the presented examples may be used, or a plurality of those among the presented examples may be used in combination unless otherwise specified.

### Atomic Layer Deposition Device

Hereinafter, an atomic layer deposition device (ALD device) according to the present exemplary embodiment may be referred to as “atomic layer deposition device (A)” or “device (A)”. Device (A) is an atomic layer deposition device that forms a compound layer on a substrate by an atomic layer deposition method (atomic layer deposition (ALD) method). Device (A) includes a conveyor for conveying a substrate in a conveyance direction and at least one deposition unit disposed to face the substrate. The deposition unit includes a plurality of feeders and a plurality of exhausters arranged along the conveyance direction to face the substrate. Each of the plurality of feeders is sandwiched between two adjacent exhausters. A plurality of feeders includes a plurality of purge gas feeders for feeding purge gas, at least one first raw material feeder for feeding a first raw material, and at least one second raw material feeder for feeding a second raw material. A compound layer is formed by repeating a step including feeding of the first raw material to the substrate and feeding of the second raw material to the substrate. The deposition unit includes a first purge region, a second purge region, and a third purge region arranged along the conveyance direction, and includes a first raw material feed region disposed between the first purge region and the second purge region, and a second raw material feed region disposed between the second purge region and the third purge region. The first raw material feed region includes at least one first raw material feeder. The second raw material feed region includes at least one second raw material feeder. At least one purge region selected from the group consisting of the first purge region, the second purge region, and the third purge region includes two or more purge gas feeders. Hereinafter, the conveyance direction of the substrate may be referred to as “conveyance direction D”.

For a substrate having a porous portion on a surface, in order to form a compound layer deep in the porous portion, it is necessary to cause a raw material to reach deep in the porous portion, and then purge the raw material that has reached deep before the next raw material is fed. Method for achieving this may include reducing the conveyance speed of the substrate or increasing the length (the length in conveyance direction D of the substrate) of a head for feeding the raw material and the like (raw material and purge gas). However, reducing the conveyance speed of the substrate lowers productivity. Meanwhile, increasing the length of the head will increase the lengths of the regions for feeding raw materials and purge gas and the intervals between exhausters. This is likely to cause a warp or undulation of the substrate, and this has been found by the inventors of the present application. Warp and undulation of the substrate may result in a non-uniform compound layer, or may cause damage to the substrate and false conveyance of the substrate.

As a result of studies, the inventors of the present application have found that by using device (A) having the configuration described above, a compound layer can be formed with high productivity and uniformity even for a substrate having a porous portion on a surface thereof. The present disclosure is based on this new finding. Device (A) can also be used for forming a compound layer on a substrate having no porous portion on a surface thereof. Even in this case, the compound layer can be formed on the substrate with high productivity and uniformity.

When forming a compound layer in a porous portion, it is particularly important to purge a raw material that has been fed. In device (A), at least one purge region selected from the group consisting of the first purge region, the second purge region, and the third purge region includes two or more purge gas feeders. Further, each of the purge gas feeders is sandwiched between two adjacent exhausters. With this configuration, purge can be performed sufficiently without making a purge gas feeder excessively long. Accordingly, warp and undulation of the substrate that may occur during film formation can be suppressed.

As the second raw material, a raw material different from the first raw material can be used. The first raw material may contain an element that bonds with oxygen to form an oxide, and the second raw material may contain oxygen. By using these raw materials, a layer of the oxide can be formed. Hereinafter, the first raw material containing an element that bonds with oxygen to form an oxide may be referred to as “precursor”. Hereinafter, the second raw material containing oxygen may be referred to as “oxidant”. The first raw material and the second raw material may be fed to the surface of the substrate in a gaseous (molecular) state or may be fed to the surface of the substrate in a plasma state. For example, the precursor may be fed to the surface of the substrate in a gaseous state.

As described above, at least one purge region selected from the group consisting of the first purge region, the second purge region, and the third purge region includes two or more purge gas feeders. Hereinafter, at least one of the purge regions may be referred to as “purge region (P)”. The number of purge gas feeders included in the purge region (P) may be two or more, or three or more, and may be less than or equal to 150, or less than or equal to 100. Here, one purge gas feeder means a feeder configured with no exhauster. Likewise, regarding the feeders other than the purge gas feeder, one feeder means a feeder configured with no exhauster.

A pitch at which the exhausters are disposed (an interval between two adjacent exhausters) may vary or be substantially constant. Making the pitches substantially constant can suppress warp, in particular, of the substrate. The distance between two adjacent exhausters may be in a range from 0.2 L to 5.0 L, inclusive (for example, in a range from 0.5 L to 2.0 L, inclusive), where L is an average distance between two adjacent exhausters. The interval between two adjacent exhausters corresponds to the length (length in conveyance direction D) of a feeder sandwiched between the two adjacent exhausters.

The distance between two adjacent exhausters may be selected in consideration of the type of the compound layer, the width of the substrate, the surface shape of the substrate, and the like. From a viewpoint of suppressing warp and the like of the substrate, the distance between two adjacent exhausters may be less than or equal to 100 mm (for example, less than or equal to 50 mm, less than or equal to 30 mm, less than or equal to 20 mm, or less than or equal to 10 mm). The distance between two adjacent exhausters may be 1 mm or more, or 3 mm or more, and may be less than or equal to 100 mm, less than or equal to 50 mm, less than or equal to 30 mm, less than or equal to 20 mm, or less than or equal to 10 mm.

When an oxide layer is to be formed on a substrate having a porous portion by the ALD method, it is important to sufficiently purge a precursor and an oxidant. When the second raw material is an oxidant, the third purge region may include two or more purge gas feeders. When the first raw material is a precursor, the second purge region may include two or more purge gas feeders.

Each of the first purge region, the second purge region, and the third purge region may include two or more purge gas feeders. According to this configuration, sufficient purge can be performed.

The second purge region is disposed between the first purge region and the third purge region. The first purge region, the second purge region, and the third purge region may be arranged in this order from the upstream side to the downstream side in the conveyance direction. Alternatively, the first purge region, the second purge region, and the third purge region may be arranged in this order from the downstream side to the upstream side in the conveyance direction. In either arrangement, a compound layer is formed by repeating a step including feed of the first raw material to the substrate and feed of the second raw material to the substrate.

Device (A) may include two or more deposition units continuously arranged along the conveyance direction. By increasing the number of deposition units, a thick compound layer can be formed. In this case, the third purge region of one of the two adjacent deposition units and the first purge region of the other of the two adjacent deposition units may or may not share one or more purge gas feeders and one or more exhausters. The number of deposition units included in device (A) is not particularly limited. The number of deposition units included in device (A) may be one or more, two or more, or three or more, and may be less than or equal to 30, or less than or equal to 20. A plurality of deposition units may be integrated or separated. Increasing the number of deposition units can increase productivity but raises the cost of the device.

The number of purge gas feeders included in the third purge region may be more than the number of purge gas feeders included in the second purge region. Examples of the second raw material include a substance that easily causes physical adsorption and is difficult to be purged (for example, water). By increasing the number of purge gas feeders included in the third purge region performing purge after feed of the second raw material, the second raw material can be sufficiently purged.

The first raw material feed region may include two or more first raw material feeders. An exhauster exists between two first raw material feeders. Thus, according to this configuration, a sufficient amount of the first raw material can be fed to the substrate, and warp and the like of the substrate can be suppressed. The number of the first raw material feeders included in the first raw material feed region is not particularly limited, and may be one or more, two or more, three or more, or less than or equal to five. Increasing this number can improve productivity but increases the cost of the device.

When the first raw material feed region includes two or more first raw material feeders, the first raw material feed region may further include at least one purge gas feeder. In this case, in the first raw material feed region, the purge gas feeder can be disposed between two adjacent first raw material feeders. According to this configuration, a partial pressure of the first raw material becoming excessively high in the first raw material feed region can be suppressed. By feeding the raw material at a partial pressure less than or equal to the vapor pressure of the raw material, precipitation of the raw material, physical adsorption of the raw material to a base material, and the like can be suppressed. As a result, dense film formation can be performed.

The second raw material feed region includes two or more second raw material feeders. An exhauster exists between two second raw material feeders. Thus, according to this configuration, a sufficient amount of the second raw material can be fed to the substrate, and warp and the like of the substrate can be suppressed. The number of the second raw material feeders included in the second raw material feed region is not particularly limited, and may be one or more, two or more, three or more, or less than or equal to five. Increasing this number can improve productivity but increases the cost of the device.

When the second raw material feed region includes two or more second raw material feeders, the second raw material feed region may further include at least one purge gas feeder. In this case, in the second raw material feed region, the purge gas feeder can be disposed between two adjacent second raw material feeders. According to this configuration, a partial pressure of the second raw material becoming excessively high in the second raw material feed region can be suppressed.

Device (A) may further include a move mechanism for moving the deposition unit along conveyance direction D. By moving the deposition unit back and forth along conveyance direction D and, during this motion, forming a compound layer, a thick compound layer can be formed using fewer deposition units.

The substrate may be a metal foil having a porous portion on a surface thereof. According to device (A), a compound layer can be formed with high productivity and uniformity even for a substrate having a porous portion on a surface thereof. The substrate may be a substrate (for example, a metal foil) having no porous portion on a surface thereof.

Using device (A), a compound layer may be formed only on one surface (one of main surfaces) of the substrate in one conveyance, or compound layers may be formed on two surfaces (two main surfaces) of the substrate in one conveyance. When the compound layers are to be formed on the two surfaces of the substrate, device (A) may include a deposition unit disposed to face one of the main surfaces of the substrate and a deposition unit disposed to face the other main surface of the substrate. Note that, compound layers may be formed on the two surfaces of the substrate by performing twice a step of forming a compound layer on one surface of the substrate in one conveyance. The two compound layers formed on the two surfaces of the substrate may be the same or different.

The present disclosure provides a substrate having a compound layer formed on a surface thereof by device (A). For example, the present disclosure provides an electrode foil for an electrolytic capacitor, and an electrolytic capacitor using the electrode foil. The electrode foil may include a metal foil having a porous portion on a surface thereof and a metal oxide layer (dielectric layer) formed on the surface (porous portion). The electrode foil can be used as an electrode foil including an anode foil and a metal oxide layer (dielectric layer) formed on the anode foil. The metal oxide layer is formed by device (A).

Examples of the constituent elements of device (A) will be described below. However, the constituent elements of device (A) are not limited to the following examples. A constituent element used in a known atomic layer deposition device may be used as a constituent element of device (A) other than the distinctive features of device (A).

### Feeder

The feeder feeds a predetermined raw material (precursors, oxidants, etc.) and purge gas. The form of the feeder is not particularly limited, and a form of a known feeder may be used. The feeder may have a discharge port for discharging a raw material. Examples of the discharge port include a slit-like discharge port extending in a direction perpendicular to conveyance direction D, a discharge port including a plurality of through holes, and a nozzle-like discharge port. The feeder is connected to a device for feeding a raw material to be discharged from the discharge port. For example, each of the first raw material feeder, the second raw material feeder, and the purge gas feeder may be connected via a mass flow controller respectively to a feed source of the first raw material, a feed source of the second raw material feeder, and a gas cylinder of purge gas.

The oxide layer formed by device (A) may be an oxide of a single element or an oxide of a plurality of kinds of elements X (composite oxide). That is, examples of the oxide formed by device (A) include a composite oxide. The composite oxide contains a plurality of types of elements X that bond with oxygen to form the composite oxide. To form a composite oxide layer by device (A), the first raw material containing a plurality of types of elements X may be fed from the first raw material feeder. In this case, the first raw material may contain a gas of a plurality of types of compounds. Alternatively, the feeder of device (A) may include at least one third feeder for feeding the third raw material different from the first raw material and the second raw material. When the first raw material and the third raw material are precursors and the second raw material is an oxidant, the first raw material feeder to third raw material feeder may be arranged in the order: the first raw material feeder, the second raw material feeder, the third raw material feeder, the second raw material feeder.

When the first raw material and the third raw material are precursors and the second raw material is an oxidant, device (A) may include region A in which the first raw material feeder and the second raw material feeder are arranged in this order, and region B in which the third raw material feeder and the second raw material feeder are arranged in this order. Device (A) may include at least either of region A and region B by a plurality of numbers. At least a part of a plurality of regions A may be continuously arranged in the order, for example: region A, region A. At least a part of a plurality of regions B may be continuously arranged the order, for example: region B, region B. When device (A) includes a plurality of regions A and a plurality of regions B, regions A and regions B may be alternately arranged, for example, in the order: region A, region B, region A, region B.

The composite oxide layer may be formed by repeating a step including feeding of the first raw material to the substrate, feeding of the second raw material to the substrate, and feeding of the third raw material to the substrate. The first raw material and the third raw material may be mixed to be fed to the substrate, or may be fed separately to the substrate.

### Exhauster

The exhauster sucks the gas not been used for compound formation after being fed to the substrate and the reaction product resulting from the reaction of the gas at the substrate. The exhauster has an exhaust port for sucking them. The shape of the exhaust port is not particularly limited, and the shape exemplified by the shape of the discharge port may be used. The exhaust port is connected to an exhaust device.

### Conveyor

The conveyor uses a mechanism for conveying the substrate. The conveyor is not particularly limited, and a known conveyance mechanism may be used. For example, a conveyance mechanism used in a manufacturing method called roll-to-roll may be used for the conveyor. An example of the conveyor includes an unwinding roll that unwinds and feeds the substrate, a winding roll that winds the substrate that has been fed, and a support that supports the substrate being conveyed. A compound layer is formed while the substrate is conveyed from the unwinding roll to the winding roll.

The support may be a roll. Alternatively, the support may include a gas bearing that ejects gas toward the substrate to support the substrate. The support may be an endless belt that supports the substrate while moving with the substrate.

### Chamber

Device (A) typically includes a chamber. The deposition unit is disposed inside the chamber. The substrate is conveyed to run inside the chamber, and a compound layer is formed inside the chamber. The inside of the chamber may be depressurized or may not be depressurized. To depressurize the inside of the chamber, device (A) includes a depressurization device.

### Others

Device (A) may include a controller to control components in device (A). As the controller, a controller similar to a controller used in a known ALD device can be used. The controller executes a program to perform control necessary for forming a compound layer. For example, the controller controls the feed amount of a raw material, the pressure inside the chamber, and the conveyance speed of the substrate. The controller can be connected to various sensors and various components. Examples of sensors include a pressure sensor and a temperature sensor. Examples of components include a motor, a heater, an electrode, a power source, and a mass flow controller. The motor can be used for conveying the substrate and moving the deposition unit.

Device (A) may include a move mechanism for moving the deposition unit back and forth along conveyance direction D of the substrate. A compound layer may be formed while moving the deposition unit. According to this configuration, a thick compound layer can be formed with fewer deposition units. This enables downsizing of the device. Device (A) may include a heating device for heating the substrate or a raw material. Device (A) may include a component for feeding a raw material in a predetermined state to the substrate. For example, device (A) may include components (electrode, power source, etc.) to turn the state of a raw material into a plasma state.

An example of the substrate on which a compound layer is formed by device (A) and an example of a compound layer to be formed will be described below. Note that, the substrate and the compound layer are not limited to the following examples.

### Substrate

The substrate is not particularly limited, but a substrate having a porous portion on a surface thereof is preferably used. For example, the substrate may be a metal foil used as an electrode foil of an electrolytic capacitor. A porous portion on a surface of a metal foil may be formed by a known method. For example, a porous portion may be formed by etching a typical metal foil having a flat surface. The width of the substrate is not limited, and may be 15 mm or more (for example, 5 cm or more) or less than or equal to 100 cm. The length of the substrate is not limited, but a long substrate can be used as the substrate. The length of the substrate may be 10 m or more (for example, 30 m or more) or less than or equal to 2000 m.

A metal foil used as an electrode foil of an electrolytic capacitor typically includes a non-porous core and a porous portion formed on an outer side of the core. The porous portion is typically formed on two surfaces (two main surfaces) of the metal foil. However, when only one surface of a metal foil is to be used, a porous portion may be formed only on one surface (one main surface) of the metal foil. The thickness of a porous portion is not particularly limited, and is selected according to the application and required characteristics of an electrolytic capacitor.

The metal foil used as an electrode foil of an electrolytic capacitor is made of a metal (first metal). The metal foil is not particularly limited, and a metal foil used for an electrode foil of an electrolytic capacitor can be used. Examples of the first metal include a valve metal and an alloy containing a valve metal. Examples of a valve metal include aluminum (Al), tantalum (Ta), niobium (Nb), and titanium (Ti).

### Compound Layer

A compound constituting a compound layer is not limited, and may be a compound formed by an atomic layer deposition method. Examples of compounds include an oxide and a nitride. A compound layer may be of only one layer of a single kind of compound, or may include a plurality of layers of different compounds.

When manufacturing an electrode foil of an electrolytic capacitor, an oxide layer (dielectric layer) may be formed as a compound layer. Examples of elements, other than oxygen, constituting an oxide layer include Al, Ta, Nb, Ti, Si, Zr, and Hf. Examples of oxides constituting an oxide layer include Al₂O₃, Ta₂O₅, Nb₂O₅, TiO₂, SiO₂, ZrO₂, HfO₂, ZnO, and a composite oxide. Examples of composite oxides include a composite oxide of titanium and silicon and a composite oxide of titanium, silicon, and aluminum. In an example manufacturing of an electrode foil of an electrolytic capacitor, an aluminum oxide layer (compound layer) is formed on an aluminum foil (substrate).

A metal element constituting a metal foil and an element, other than oxygen, contained in an oxide layer may be the same or different. Unlike a method of forming an oxide layer by an anodizing treatment, in the ALD method, a metal element constituting a metal foil and a metal element contained in an oxide layer may be different.

The thickness of a compound layer is selected depending on the purpose. The thickness of the oxide layer (dielectric layer) formed for manufacturing an electrode foil of an electrolytic capacitor may be 1 nm or more, or 5 nm or more, and may be less than or equal to 300 nm, or less than or equal to 200 nm.

A precursor (first raw material) for forming an oxide layer is selected depending on the composition of the oxide layer. The precursor is not particularly limited, and an organic compound conventionally used in the ALD method may be used. Examples of the precursor containing Al include trimethylaluminum ((CH₃)₃Al).

Examples of oxidant include water, oxygen, and ozone. An oxidant may be fed to the surface of the substrate in a state of plasma of which raw material is the oxidant. An inert gas for purge is not particularly limited, and a known inert gas (for example, nitrogen gas) can be used.

Hereinafter, an example of atomic layer deposition device (A) and an example of forming a compound layer using atomic layer deposition device (A) will be specifically described with reference to the drawings. The examples described below can be modified based on the above description. Matters described below may be applied to the exemplary embodiment described above.

### First Exemplary Embodiment

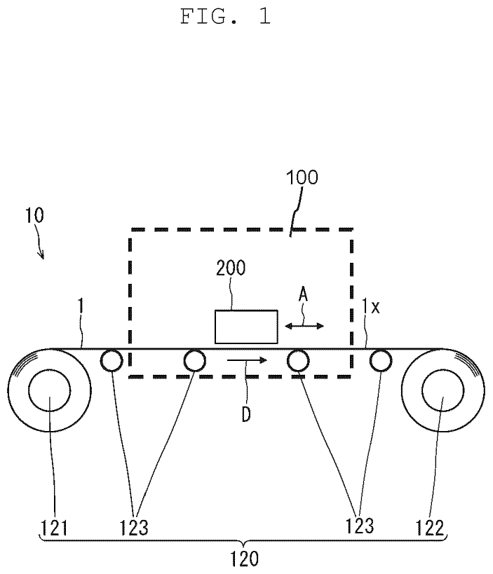

FIG. 1 schematically illustrates a configuration of device (atomic layer deposition device) 10 of a first exemplary embodiment. Device 10 is an example of device (A). Device 10 includes chamber 100, conveyor 120, and deposition unit 200. Deposition unit 200 is disposed inside chamber 100. Conveyor 120 includes unwinding roll 121, winding roll 122, and conveyance roll 123. Conveyor 120 conveys long substrate 1. FIG. 1 illustrates conveyance direction D of substrate 1 in chamber 100. Deposition unit 200 is disposed so as to face one main surface of substrate 1. Device 10 may include a mechanism for moving deposition unit 200 back and forth along conveyance direction D as illustrated by arrow A. Device 10 may include a heater for heating substrate 1 or a raw material. Device 10 may include various sensors such as a temperature sensor and a pressure sensor.

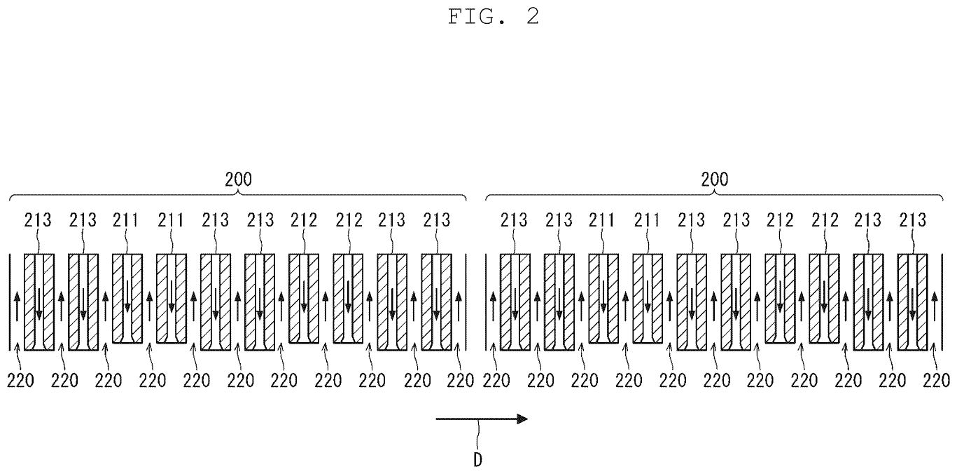

An example of a configuration of deposition unit 200 is illustrated in FIG. 2. Deposition unit 200 illustrated in FIG. 2 includes a plurality of feeders 210 and a plurality of exhausters (exhaust passages) 220. The plurality of feeders 210 and the plurality of exhausters 220 are arranged along conveyance direction D so as to face substrate 1. Each of the plurality of feeders 210 is sandwiched between two exhausters 220. That is, exhausters 220 exist on two sides of feeder 210.

Deposition unit 200 includes first raw material feeder 211 which is feeder 210, second raw material feeder 212 which is feeder 210, and purge gas feeder 213 which is feeder 210. Each feeder is connected to a feed source of a raw material or purge gas. First raw material is fed to substrate 1 from an opening of first raw material feeder 211. Second raw material is fed to substrate 1 from an opening of second raw material feeder 212. Purge gas is fed to substrate 1 from an opening of purge gas feeder 213. Exhauster 220 is connected to an exhaust device and sucks excess gas and unnecessary reaction products. Substrate 1 that has passed in front of deposition unit 200 is substrate Ix on which a compound layer has been formed. Note that deposition unit 200 is also referred to as deposition head.

Deposition unit 200 includes first purge region PR1, second purge region PR2, third purge region PR3, first raw material feed region MR1, and second raw material feed region MR2. These are arranged in the order in conveyance direction D from the upstream side to the downstream side: first purge region PR1, first raw material feed region MRI, second purge region PR2, second raw material feed region MR2, third purge region PR3. Each of first purge region PR1, second purge region PR2, and third purge region PR3 includes two purge gas feeders 213. First raw material feed region MR1 includes two first raw material feeders 211. Second raw material feed region MR2 includes two second raw material feeders 212

An example of forming an oxide layer on substrate 1 by device 10 will be described below. Regarding an example where deposition unit 200 does not move, a compound layer formed by one deposition unit 200 will be described.

When forming an oxide layer, a precursor gas (first raw material), an oxidant (second raw material), and purge gas are fed from the feeders to substrate 1, and are exhausted from exhausters 220.

Substrate 1 moves along conveyance direction D. Substrate 1 (a portion of substrate 1) that is conveyed is sequentially treated in first purge region PR1, first raw material feed region MR1, second purge region PR2, second raw material feed region MR2, and third purge region PR3 in this order. First, purge is performed in first purge region PR1. Next, in first raw material feed region MR1, a precursor gas (first raw material) is fed from first raw material feeder 211 to substrate 1. Next, purge is performed in second purge region PR2. Next, in second raw material feed region MR2, an oxidant (second raw material) is fed from second raw material feeder 212 to substrate 1. An oxide layer is thereby formed on substrate 1. Next, purge is performed in third purge region PR3. By moving deposition unit 200 or substrate 1 back and forth or by using a plurality of deposition units 200, a thick oxide layer can be formed.

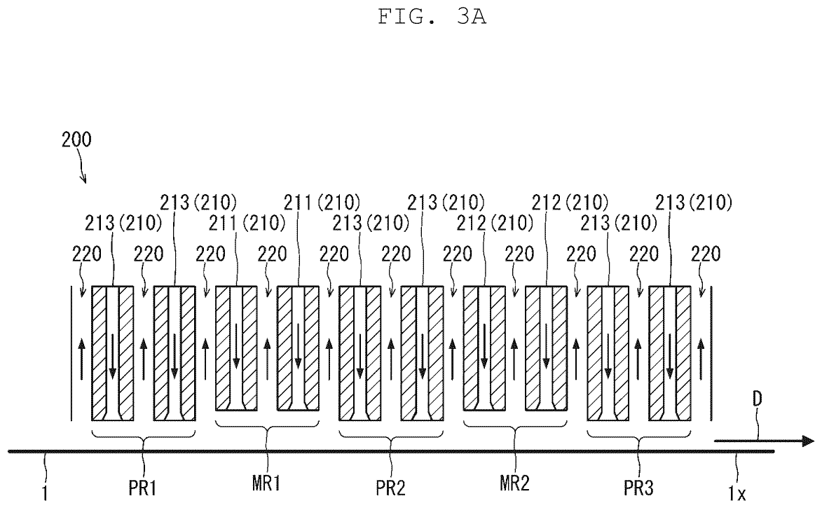

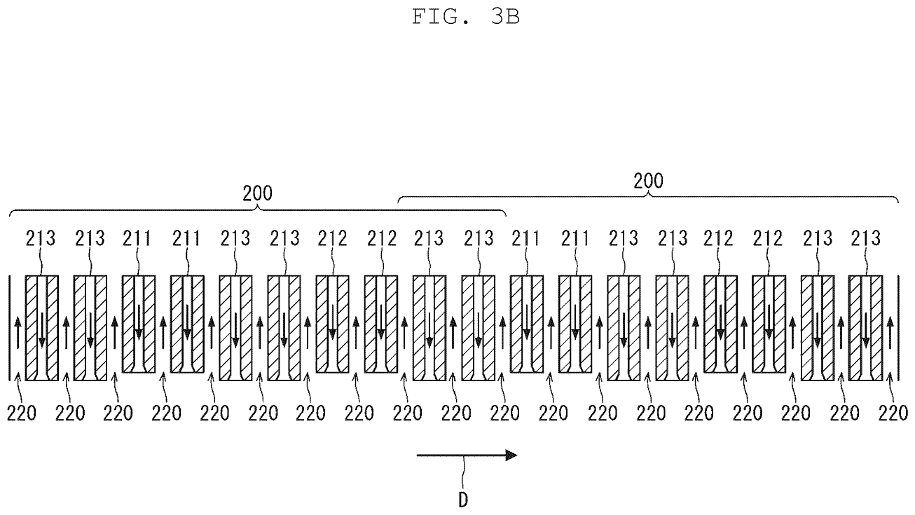

As described above, device 10 may include the plurality of deposition units 200. The plurality of deposition units 200 may be integrated or separated FIG. 3A schematically illustrates a configuration of a part of an example in which device 10 includes the plurality of deposition units 200. In the example illustrated in FIG. 3A, two adjacent deposition units 200 do not share feeder 210 nor exhauster 220. FIG. 3B schematically illustrates a configuration of a part of another example in which device 10 includes the plurality of deposition units 200. In the example illustrated in FIG. 3B, it may be considered that two adjacent deposition units 200 share one or more purge gas feeders 213 and one or more exhausters 220. In this case, at least a part of third purge region PR3 of deposition unit 200 on the upstream side serves as at least a part of first purge region PR1 of deposition unit 200 on the downstream side.

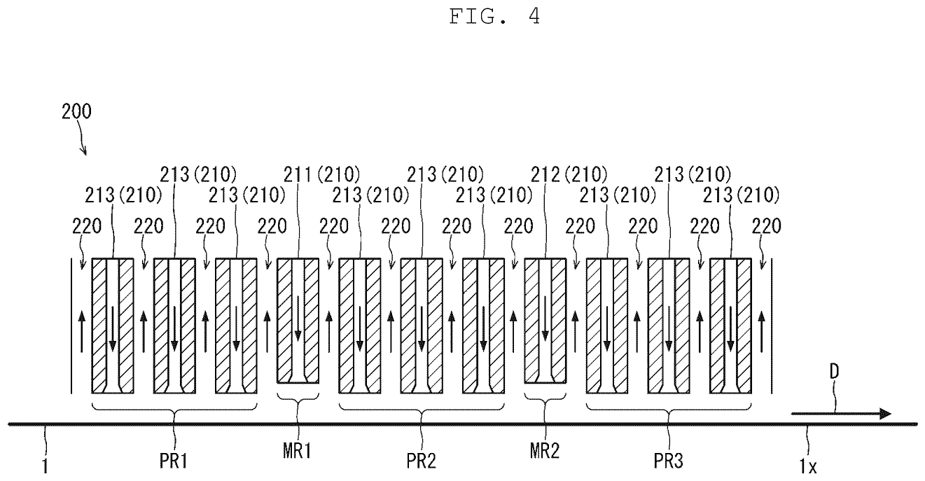

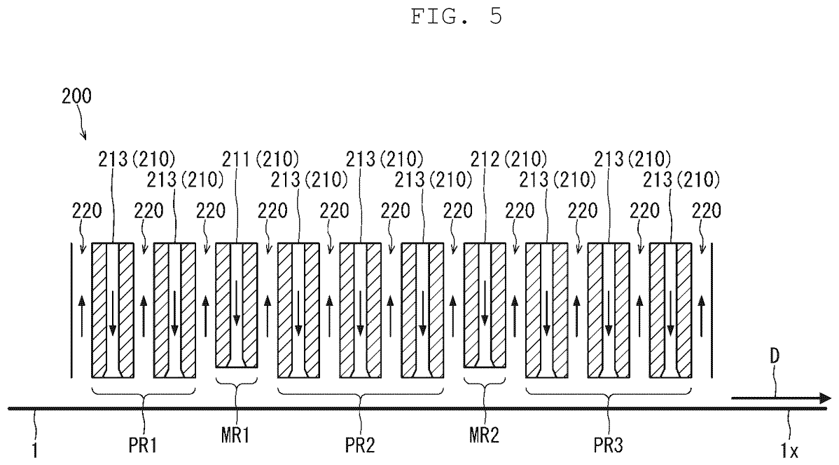

Note that the number of purge gas feeders 213 included in each purge region, the number of first raw material feeders 211 included in first raw material feed region MR1, and the number of second raw material feeders 212 included in second raw material feed region MR2 are not limited to the numbers illustrated in the drawings described above. Examples of deposition units 200 where the numbers are varied are illustrated in FIGS. 4 and 5.

In deposition unit 200 illustrated in FIG. 4, each of first purge region PR1 to third purge region PR3 includes three purge gas feeders 213. First raw material feed region MRI includes one first raw material feeder 211. Second raw material feed region MR2 includes one second raw material feeder 212.

In deposition unit 200 illustrated in FIG. 5, first purge region PR1 includes two purge gas feeders 213. Each of second purge region PR2 and third purge region PR3 includes three purge gas feeders 213. First raw material feed region MR1 includes one first raw material feeder 211. Second raw material feed region MR2 includes one second raw material feeder 212.

In the exemplary embodiment described above, an example has been described in which the purge regions are arranged from the upstream side to the downstream side in the order: first purge region PR1, second purge region PR2, third purge region PR3. However, the purge regions may be arranged from the upstream side to the downstream side in the order: third purge region PR3, second purge region PR2, first purge region PR1.

### Supplementary Note

The above description discloses following techniques.

### (Technique 1)

An atomic layer deposition device for forming a compound layer on a substrate by an atomic layer deposition method, the device including:
a conveyor for conveying the substrate in a conveyance direction, and
at least one deposition unit disposed to face the substrate,
in which the deposition unit includes a plurality of feeders and a plurality of exhausters, the plurality of feeders and plurality of exhausters being arranged along the conveyance direction to face the substrate,
each of a plurality of feeders is sandwiched between adjacent two of the exhausters,
a plurality of feeders includes a plurality of purge gas feeders for feeding a purge gas, at least one first raw material feeder for feeding a first raw material, and at least one second raw material feeder for feeding a second raw material,
formation of the compound layer includes repetition of a process including feeding of the first raw material to the substrate and feeding of the second raw material to the substrate,
the deposition unit includes
   a first purge region, a second purge region, and a third purge region arranged along the conveyance direction,
   a first raw material feed region disposed between the first purge region and the second purge region, and
   a second raw material feed region disposed between the second purge region and the third purge region,
the first raw material feed region includes the at least one first raw material feeder,
the second raw material feed region includes the at least one second raw material feeder, and
at least one purge region selected from the group consisting of the first purge region, the second purge region, and the third purge region includes two or more of the purge gas feeders.

### (Technique 2)

The atomic layer deposition device according to Technique 1, in which
the first raw material contains an element that bonds with oxygen to form an oxide,
the second raw material contains oxygen, and
the compound layer is a layer of the oxide.

### (Technique 3)

The atomic layer deposition device according to Technique 1 or 2, in which each of the first purge region, the second purge region, and the third purge region includes two or more of the purge gas feeders.

### (Technique 4)

The atomic layer deposition device according to any one of Techniques 1 to 3, in which the first purge region, the second purge region, and the third purge region are aligned along the conveyance direction from an upstream side to a downstream side in an order of the first purge region, the second purge region, and the third purge region.

### (Technique 5)

The atomic layer deposition device according to any one of Techniques 1 to 3, in which the first purge region, the second purge region, and the third purge region are aligned along the conveyance direction from a downstream side to an upstream side in an order of the first purge region, the second purge region, and the third purge region.

### (Technique 6)

The atomic layer deposition device according to any one of Techniques 1 to 5, further including two or more of the deposition units continuously arranged along the conveyance direction.

### (Technique 7)

The atomic layer deposition device according to Technique 6, in which the third purge region of one of two adjacent ones of the deposition units and the first purge region of another of the two adjacent ones of the deposition units share one or more of the purge gas feeders and one or more of the exhausters.

### (Technique 8)

The atomic layer deposition device according to any one of Techniques 1 to 7, in which the number of the purge gas feeders included in the third purge region is more than the number of the purge gas feeders included in the second purge region.

### (Technique 9)

The atomic layer deposition device according to any one of Techniques 1 to 8, in which the first raw material feed region includes two or more of the first raw material feeders.

### (Technique 10)

The atomic layer deposition device according to Technique 9, in which
the first raw material feed region further includes at least one of the purge gas feeders, and
in the first raw material feed region, the purge gas feeder is disposed between adjacent two of the first raw material feeders.

### (Technique 11)

The atomic layer deposition device according to any one of Techniques 1 to 10, in which the second raw material feed region includes two or more of the second raw material feeders.

### (Technique 12)

The atomic layer deposition device according to Technique 11, in which
the second raw material feed region further includes at least one of the purge gas feeders, and
in the second raw material feed region, the purge gas feeder is disposed between adjacent two of the second raw material feeders.

### (Technique 13)

The atomic layer deposition device according to any one of Techniques 1 to 12, further including a move mechanism that moves the deposition unit along the conveyance direction.

### (Technique 14)

The atomic layer deposition device according to any one of Techniques 1 to 13, in which the substrate is a metal foil having a porous portion on a surface of the substrate.

### INDUSTRIAL APPLICABILITY

The present disclosure can be used for an atomic layer deposition device.

### REFERENCE MARKS IN THE DRAWINGS

1 substrate
10 device (atomic layer deposition device)
100 chamber
120 conveyor
200 deposition unit
210 feeder
211 first raw material feeder
212 second raw material feeder
213 purge gas feeder
220 exhauster
D conveyance direction
MR1 first raw material feed region
MR2 second raw material feed region
PR1 first purge region
PR2 second purge region
PR3 third purge region

1. An atomic layer deposition device for forming a compound layer on a substrate by an atomic layer deposition method, the device comprising:
a conveyor that conveys the substrate in a conveyance direction; and
a deposition unit disposed to face the substrate, wherein:
the deposition unit includes a plurality of feeders and a plurality of exhausters, the plurality of feeders and plurality of exhausters being arranged along the conveyance direction to face the substrate,
each of the plurality of feeders is sandwiched between corresponding two exhausters adjacent to each other among the plurality of exhausters,
the plurality of feeders includes a plurality of purge gas feeders that feed a purge gas, a first raw material feeder that feeds a first raw material, and a second raw material feeder that feeds a second raw material,
the deposition unit is configured to form of the compound layer by repetition of a process including feeding of the first raw material to the substrate and feeding of the second raw material to the substrate,
the deposition unit includes:
a first purge region, a second purge region, and a third purge region arranged along the conveyance direction,
a first raw material feed region disposed between the first purge region and the second purge region, and
a second raw material feed region disposed between the second purge region and the third purge region,
the first raw material feed region includes the at least one first raw material feeder,
the second raw material feed region includes the at least one second raw material feeder, and
at least one purge region selected from the group consisting of the first purge region, the second purge region, and the third purge region includes two or more of the plurality of purge gas feeders.

2. The atomic layer deposition device according to claim 1, wherein:
the first raw material contains an element that bonds with oxygen to form an oxide,
the second raw material contains oxygen, and
the compound layer is a layer of the oxide.

3. The atomic layer deposition device according to claim 1, wherein each of the first purge region, the second purge region, and the third purge region includes two or more of the plurality of purge gas feeders.

4. The atomic layer deposition device according to claim 1, wherein the first purge region, the second purge region, and the third purge region are aligned along the conveyance direction from an upstream side to a downstream side in an order of the first purge region, the second purge region, and the third purge region.

5. The atomic layer deposition device according to claim 1, wherein the first purge region, the second purge region, and the third purge region are aligned along the conveyance direction from a downstream side to an upstream side in an order of the first purge region, the second purge region, and the third purge region.

6. The atomic layer deposition device according to claim 1, further comprising two or more deposition units continuously arranged along the conveyance direction, each of the two or more deposition units being the deposition unit.

7. The atomic layer deposition device according to claim 6, wherein the third purge region of one of two adjacent deposition units among the two or more deposition units and the first purge region of another of the two adjacent deposition units among the two or more deposition units share one or more of the plurality of purge gas feeders and one or more of the plurality of exhausters.

8. The atomic layer deposition device according to claim 1, wherein a number of the plurality of purge gas feeders included in the third purge region is more than a number of the plurality of purge gas feeders included in the second purge region.

9. The atomic layer deposition device according to claim 1, wherein the first raw material feed region includes two or more first raw material feeders, each of the two or more first raw material feeders being the first raw material feeder.

10. The atomic layer deposition device according to claim 9, wherein
the first raw material feed region further includes at least one of the plurality of purge gas feeders, and
in the first raw material feed region, the at least one of the plurality of purge gas feeders is disposed between corresponding two first raw material feeders adjacent to each other among the two or more first raw material feeders.

11. The atomic layer deposition device according to claim 1, wherein the second raw material feed region includes two or more second raw material feeders, each of the two or more second raw material feeders being the second raw material feeder.

12. The atomic layer deposition device according to claim 11, wherein
the second raw material feed region further includes at least one of the plurality of purge gas feeders, and
in the second raw material feed region, the at least one of the plurality of purge gas feeders is disposed between corresponding two second raw material feeders among the two or more second raw material feeders.

13. The atomic layer deposition device according to claim 1, further comprising a move mechanism that moves the deposition unit along the conveyance direction.

14. The atomic layer deposition device according to claim 1, wherein the substrate is a metal foil having a porous portion on a surface of the substrate.
